(19) United States
(12) Patent Application Publication
(10) Pub. No.: US 2011/0216247 A1
(43) Pub. Date: Sep. 8, 2011

(54) SIGNAL PROCESSING DEVICE, SIGNAL PROCESSING METHOD, INTEGRATED CIRCUIT FOR SIGNAL PROCESSING, AND TELEVISION RECEIVER

(76) Inventor: Hideshi Nishida, Hyogo (JP)

(21) Appl. No.: 12/671,542

(22) PCT Filed: Jun. 3, 2009
(86) PCT No.: PCT/JP2009/002496

§ 371 Date: Feb. 1, 2010

(30) Foreign Application Priority Data
May 6, 2008 (JP) 2008-147753

(51) Int. Cl. H04N 5/44; H03K 19/173

(52) U.S. Cl. 348/725; 326/38; 348/E05.096

(57) ABSTRACT

A signal processing device includes a first and a second reconfigurable circuit whose logic configuration can be changed. With the reconfigurable circuits sequentially reconfigured, the signal processing device conducts processes regarding signals transmitted to and from a connected external device. At a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the external device and an internal interface connected to an internal device, with the first reconfigurable circuit inserted into the signal transmission path. At a second temporal point that is after completion of the reconfiguration of the second reconfigurable circuit, the second configurable circuit is inserted in the signal transmission path between the first reconfigurable circuit and the internal interface.

### TECHNICAL FIELD

The present invention relates to signal processing devices having reconfigurable circuits, and more particularly to a technology for reducing the startup time, which is the time taken from the start of power supply to the start of processing.

### BACKGROUND ART

Conventionally, there are reconfigurable circuits whose logic circuit configuration can be changed after manufacturing. PLD (Programmable Logic Device) and FPGA (Field Programmable Gate Array) are examples of such circuits (see, for example, Patent Literatures 1 and 2 listed below).

Being fed with data defining the topology of connections between internal components (hereinafter, such data is referred to as “configuration information”), a reconfigurable circuit is changed into a specific logic configuration according to the configuration information. That is, the same reconfigurable circuit is used to implement a circuit that performs a different process, simply by rewriting configuration information, which is easier as compared with the implementation with a conventional LSI (Large Scale Integration) having a circuit configuration that cannot be changed once it is manufactured. By virtue of this flexibility, reconfigurable circuits offer an advantage of being usable in various devices and appliances.

However, a reconfigurable circuit is not capable of retaining the circuit configuration without power supply. Therefore, it is required to newly feed configuration information to the reconfigurable circuit each time the power is turned back on. Typically, it takes tens to hundreds of milliseconds from the start of feeding configuration information until the reconfigurable circuit having received the configuration information becomes ready to execute the intended process (hereinafter, this operation is referred to as “reconfiguration”). The time taken for reconfiguration leads to a problem that the time between the power on and the processing start increases.

One known method addressing the above problem is to employ a dedicated IC (Integrated Circuit) for handling the processing during the time from the power on to the completion of reconfiguration of the reconfigurable circuit. Once the reconfiguration is completed, the processing is then handled by the reconfigurable circuit (see Patent Literature 3, for example).

### CITATION LIST

### Patent Literature

### [Patent Literature 1]

JP Patent Application Publication No. 2001-291484

### [Patent Literature 2]

JP Patent Application Publication No. 2000-151388

### [Patent Literature 3]

JP Patent Application Publication No. 2006-279322

### SUMMARY OF INVENTION

### Technical Problem

However, it should be noted that the method disclosed in Patent Literature 3 employs a dedicated IC. In order to duly embed an IC in a device having a different function, there rises another problem that the IC needs to be modified specifically for the device.

The present invention is made in view of the above problems and aims to provide a signal processing device, a signal processing method, an integrated circuit for signal processing, and a television receiver, each of which reduces the startup time from the start of power supply to the start of processing, without employing a dedicated IC for handling the processing during reconfiguration.

### Solution to Problem

In order to achieve the above aim, one aspect of the present invention provides a signal processing device that includes a first reconfigurable circuit and a second reconfigurable circuit. A logic configuration of each reconfigurable circuit is alterable. The reconfigurable circuits are sequentially reconfigured so that the signal processing device conducts processes relating to signals transmitted to and from a connected external device. The signal processing device includes memory and a control unit. The memory is operable to store first configuration information and second configuration information to be used for reconfiguring the first and second reconfigurable circuits. The control unit is operable to performs such control that: at a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the external device and an internal interface connected to an internal device, with the first reconfigurable circuit inserted into the signal transmission path; and at a second temporal point that is after completion of the reconfiguration of the second reconfigurable circuit, the signal transmission path is altered to insert the second configurable circuit between the first reconfigurable circuit and the internal interface.

### Advantageous Effects of Invention

With the structure stated above, the signal processing device according to the present invention ensures the following as of the first temporal point at which the reconfiguration of the second reconfigurable circuit is not yet completed. That is, a signal transmitted between the external and internal devices is the signal resulting from the process conducted by the first reconfigurable circuit having been reconfigured. In other words, the signal processing device according to the present invention reduces the startup time taken from the start of power supply to the start of signal transmission between the external and internal devices, as compared with the case where the signal transmission between the external and internal devices cannot be started until reconfiguration of the second reconfigurable circuit is completed.

Optionally, the first reconfigurable circuit having been reconfigured may conduct a process of converting a signal format between an internal format and an external format. The internal and external formats are mutually different and supported by the internal and external devices, respectively. The second reconfigurable circuit having been reconfigured may conduct a process of changing data carried by the signal in the internal format, without changing the format. The signal processing device may further include a selector located in the signal transmission path between the first reconfigurable circuit and the internal interface. The selector is operable to switch a connection topology relating to whether or not the second configurable circuit is inserted. The control unit may be operable to: sequentially feed the first configuration information to the first reconfigurable circuit and the second configuration information to the second reconfigurable circuit from the memory, thereby to cause the reconfiguration of each reconfigurable circuit; and control the selector to switch the connection topology so that the second reconfigurable circuit is not inserted at the first temporal point, and that the second reconfigurable circuit is inserted at the second temporal point.

In order to start the signal transmission between the internal and external devices, the signal format needs to be converted between the respective formats supported by the internal and external devices. With the structure stated above, this process of converting the signal format is performed by the first reconfigurable circuit having been reconfigured, so that the signal transmission between the internal and external devices can be started without waiting for completion of the reconfiguration of the second reconfigurable circuit. That is to say, the above structure reduces the startup time from the start of power supply to the start of signal transmission between the external and internal devices.

Further, the format conversion process performed by the first reconfigurable circuit can be changed simply by rewriting the first configuration information. Consequently, the signal processing device according to the present invention ensures to reduce the startup time taken to start the signal transmission between the internal and external devices, regardless of the type of the external device connected to the signal processing device.

Optionally, the external device may be an image signal input device. The first reconfigurable circuit having been reconfigured may be operable to conduct the format conversion process through which an image signal received in the external format from the input device via the external interface is converted into the internal format, and to output the image signal converted into the internal format. The second configurable circuit having been reconfigured may be operable to conduct the data change process through which the image signal received in the internal format from the first reconfigurable circuit having been reconfigured is corrected, and to output the corrected image signal to the internal interface.

With the structure stated above, the internal device starts to receive an image signal in the internal format as of the first temporal point, so that the internal device can start processing based on the received image signal. As of the second temporal point, the internal device starts to receive an image signal in the internal format and has been corrected through the image correction process. Here, by causing the second reconfigurable circuit to conduct such an image correction process to improve the image quality, the subsequent processing by the internal device is performed based on the image signal of higher image quality. That is, the signal processing device according to the present invention achieves to start processing relatively soon after the start of power supply and also achieves to ensure that the image processing is performed based on images of higher quality after the passage of time.

Optionally, the signal processing device may further include a third reconfigurable circuit and a fourth reconfigurable circuit. A logic configuration of each reconfigurable circuit being alterable. The signal processing device may be additionally connected to a display device. The memory may be further operable to store third configuration information and fourth configuration information to be used for reconfiguring the third and fourth reconfigurable circuits. The signal processing device may further include a second control unit operable to perform such control that: at a temporal point that is after completion of reconfiguration of the third reconfigurable circuit based on the third configuration information and before completion of reconfiguration of the fourth reconfigurable circuit based on the fourth configuration information, a second signal transmission path is formed between a second external interface connected to the display device and a second internal interface connected to a second internal device, with the third reconfigurable circuit inserted into the second signal transmission path; at a temporal point after completion of the reconfiguration of the fourth reconfigurable circuit based on the fourth configuration information, the second signal transmission path is altered to inset the fourth reconfigurable circuit between the third reconfigurable circuit and the second internal interface. At a temporal point that is after completion of the reconfiguration of the first reconfigurable circuit, the second control unit may be operable to sequentially feed the third configuration information to the third reconfigurable circuit and the fourth configuration information to the fourth reconfigurable circuit from the memory, thereby to cause the reconfiguration of each of the third and fourth reconfigurable circuits.

With the structure stated above, in parallel with the processing performed by the internal device on the signal received from the input device described above, the display device is enabled to present images based on the image signal output from the third reconfigurable circuit, as of the time at which the reconfiguration of the fourth reconfigurable circuit is not completed yet. Note that the signal output from the third reconfigurable circuit is obtained by conducting the process on the image signal fed from the second internal device. For example, by making an arrangement to feed an image signal received by the internal device described above to the second internal device, the display device is enabled to display images based on the image signal fed from the input device.

Optionally, the external device may be a display device. The second reconfigurable circuit having been reconfigured may be operable to conduct the data change process through which an image signal received in the internal format from the internal device via the internal interface is corrected, and to output the corrected image signal in the internal format to the first reconfigurable circuit having been reconfigured. The first reconfigurable circuit having been reconfigured may be operable to conduct the format conversion process through which the image signal received in the internal format from the second reconfigurable circuit having been reconfigured is converted into the external format, and to output the image signal converted into the external format to the display device via the external interface.

With the structure stated above, the display device starts to receive the image signal in the external format as of the first temporal point, which enables the display device to present images based on the received image signal. As of the second temporal point, the display device starts to receive the corrected image signal in the external format to improve the image quality, which enables the display device to present high quality images. That is, the signal processing device according to the present invention ensures that the image display is started relatively soon after the start of power supply and that the quality of images displayed improve after the passage of time.

Optionally, the signal processing device may further include a third reconfigurable circuit. A logic configuration of the third reconfigurable circuit is alterable. The second configuration information may be stored in the memory in a compressed state. The memory may be further operable to store, in a non-compressed state, third configuration information to be used for reconfiguring the third reconfigurable circuit. At a temporal point after completion of the reconfiguration of the first reconfigurable circuit based on the first configuration information and before the second configuration information is started to be fed to the second reconfigurable circuit, the control unit may be further operable to feed the third configuration information to the third reconfigurable circuit from the memory, thereby to cause the reconfiguration of the third reconfigurable circuit. The third reconfigurable circuit having been reconfigured based on the third configuration information may be operable to decompress the second configuration information fed from the memory. The control unit is further operable to feed to the second reconfigurable circuit the second configuration information decompressed by the third reconfigurable circuit having been reconfigured, thereby to cause the reconfiguration of the second reconfigurable circuit.

With the structure stated above, the third reconfigurable circuit having been configured based on the third configuration information decompresses the compressed second configuration information. As a result, the second reconfigurable circuit is reconfigured in the same manner as in the case where the second configuration information is stored in the memory in a non-compressed state. In addition, since the second configuration information is stored in a compressed state, the amount of data stored in the memory is reduced.

Optionally, the memory may be further operable to store, in a non-compressed state, fourth configuration information to be used for reconfiguring the third reconfigurable circuit. At a temporal point after completion of the reconfiguration of the second reconfigurable circuit, the control unit may be operable to: feed the fourth configuration information to the third reconfigurable circuit from the memory, thereby to cause the reconfiguration of the third reconfigurable circuit; and to alter the signal transmission path to insert the third reconfigurable circuit between the second reconfigurable circuit and the internal interface.

With the structure stated above, by defining the fourth configuration information to reconfigure a circuit that conducts a process other than the decompression process of the second configuration information, the third reconfigurable circuit reconfigured based on the fourth configuration information is effectively used. Otherwise, once reconfiguration of the second reconfigurable circuit is completed based on the decompressed second configuration information, the third reconfigurable circuit that performs the decompression process of the second configuration information becomes useless.

Optionally, the signal processing device may further include a third reconfigurable circuit and a fourth reconfigurable circuit. A logic configuration of each reconfigurable circuit is alterable. The second configuration information may be stored in the memory in a compressed state. The memory may be further operable to store, in a non-compressed state, third configuration information, fourth configuration information, and fifth configuration information to be used for reconfiguring the third and fourth reconfigurable circuits. At a temporal point after completion of the reconfiguration of the first reconfigurable circuit based on the first configuration information and before the second configuration information is started to be fed to the second reconfigurable circuit, the control unit may be further operable to feed the fifth configuration information to the fourth reconfigurable circuit from the memory, thereby to cause reconfiguration of the fourth reconfigurable circuit. The fourth reconfigurable circuit having been reconfigured based on the fifth configuration information may be operable to feed the third configuration information to the third reconfigurable circuit from the memory, thereby to cause reconfiguration of the third reconfigurable circuit. The third reconfigurable circuit having been reconfigured based on the third configuration information may be operable to decompress the second configuration information fed from the memory. The fourth reconfigurable circuit having been reconfigured based on the fifth configuration information may be operable to feed, to the second reconfigurable circuit, the second configuration information decompressed by the third reconfigurable circuit having been reconfigured, thereby to cause the reconfiguration of the second reconfigurable circuit. At a temporal point after completion of the reconfiguration of the second reconfigurable circuit, the fourth reconfigurable circuit having been reconfigured may be further operable to: feed the fourth configuration information to the third reconfigurable circuit from the memory, thereby to cause reconfiguration of the third reconfigurable circuit; and alter the signal transmission path to insert the third reconfigurable circuit between the second reconfigurable circuit and the internal interface.

With the structure stated above, having been reconfigured based on the fifth configuration information, the fourth reconfigurable circuit starts to conduct a process relating to the control of the reconfiguration of the second reconfigurable circuit, which eliminates the need for the control unit to perform the control process. As a result, the processing load imposed on the control unit is reduced.

Further, the second reconfigurable circuit is reconfigured in the same manner as in the case where the second configuration information is stored in the memory in a non-compressed state. In addition, since the second configuration information is stored in a compressed state, the amount of data stored in the memory is reduced.

Further, by defining the fourth configuration information to reconfigure a circuit that conducts a process other than the decompression process of the second configuration information, the third reconfigurable circuit reconfigured based on the fourth configuration information is effectively used.

Optionally, the memory may be further operable to store, in a non-compressed state, sixth configuration information to be used for reconfiguring the fourth reconfigurable circuit. At a temporal point after completion of the reconfiguration of the third reconfigurable circuit based on the fourth configuration information, the control unit may be further operable to feed the sixth configuration information to the forth reconfigurable circuit from the memory, thereby to cause reconfiguration of the fourth reconfigurable circuit.

With the structure stated above, by defining the sixth configuration information to reconfigure a circuit that conduces a process different from the control process relating to the reconfiguration of the second and third reconfigurable circuits, the fourth reconfigurable circuit reconfigured based on the sixth configuration information is effectively used. Otherwise, once the reconfiguration of the second and third reconfigurable circuits are completed, the fourth reconfigurable circuit that conducts the control process relating to the reconfiguration becomes useless.

In order to achieve the above aim, another aspect of the present invention provides an integrated circuit for signal processing. The integrated circuit includes a first reconfigurable circuit and a second reconfigurable circuit. A logic configuration of each reconfigurable circuit is alterable. The reconfigurable circuits are sequentially reconfigured so that the integrated circuit conducts processes relating to signals transmitted to and from a connected external device. The integrated circuit includes memory and a control unit. The memory is operable to store first configuration information and second configuration information to be used for reconfiguring the first and second reconfigurable circuits. The control unit is operable to perform such control that: at a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the external device and an internal interface connected to an internal device, with the first reconfigurable circuit inserted into the signal transmission path; and at a second temporal point that is after completion of the reconfiguration of the second reconfigurable circuit, the signal transmission path is altered to insert the second configurable circuit between the first reconfigurable circuit and the internal interface.

With the structure stated above, the integrated circuit for signal processing according to the present invention ensures the following as of the first temporal point at which the reconfiguration of the second reconfigurable circuit is not yet completed. That is, a signal transmitted between the external and internal devices is the signal resulting from the process conducted by the first reconfigurable circuit having been reconfigured. In other words, the integrated circuit for signal processing according to the present invention reduces the startup time taken from the start of power supply to the start of signal transmission between the external and internal devices, as compared with the case where the signal transmission between the external and internal devices cannot be started until reconfiguration of the second reconfigurable circuit is completed.

Optionally, the integrated circuit may further include a third reconfigurable circuit and a fourth reconfigurable circuit. A logic configuration of each reconfigurable circuit is alterable. The integrated circuit may be additionally connected to a second external device. The memory may be further operable to store third configuration information and fourth configuration information to be used for reconfiguring the third and fourth reconfigurable circuits. The integrated circuit may further include a second control unit operable to perform such control that: at a temporal point that is after completion of reconfiguration of the third reconfigurable circuit based on the third configuration information and before completion of reconfiguration of the fourth reconfigurable circuit based on the fourth configuration information, a second signal transmission path is formed between a second external interface connected to the second external device and a second internal interface connected to a second internal device, with the third reconfigurable circuit inserted into the second signal transmission path; and at a temporal point after completion of the reconfiguration of the fourth reconfigurable circuit based on the fourth configuration information, the second signal transmission path is altered to inset the fourth reconfigurable circuit between the third reconfigurable circuit and the second internal interface. After completion of the reconfiguration of the first reconfigurable circuit, the second control unit may be operable to sequentially feed the third configuration information to the third reconfigurable circuit and the fourth configuration information to the fourth reconfigurable circuit from the memory, thereby to cause the reconfiguration of each of the third and fourth reconfigurable circuits.

With the structure stated above, in parallel with the signal transmission between the external and internal devices, the following is ensured as of the temporal point at which reconfiguration of the fourth reconfigurable circuit is not yet completed. That is, the signal processed by the third reconfigurable circuit having been reconfigured is started to be transmitted between the second internal device and the second external device.

In order to achieve the above aim, yet another aspect of the present invention provides a television receiver that includes a display, a first reconfigurable circuit and a second reconfigurable circuit. A logic configuration of each reconfigurable circuit is alterable. The reconfigurable circuits are sequentially reconfigured so that the television receiver conducts processes relating to broadcast signals to be output to the display. The television receiver includes memory and a control unit. The memory is operable to store first configuration information and second configuration information to be used for reconfiguring the first and second reconfigurable circuits. The control unit is operable to perform such control that: at a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the display and an internal interface connected to an internal device for conducting a process related to received broadcast signals, with the first reconfigurable circuit inserted into the signal transmission path; and at a second temporal point that is after completion of the reconfiguration of the second reconfigurable circuit, the signal transmission path is altered to insert the second configurable circuit between the first reconfigurable circuit and the internal interface.

With the structure stated above, the television receiver according to the present invention is enabled to ensure the following as of the first temporal point at which reconfiguration of the second reconfigurable circuit is not completed yet. That is, the television receiver starts to output, to the display, a broadcast signal processed by the first reconfigurable circuit having been reconfigured. In other words, the television receiver according to the present invention reduces the startup time taken from the start of power supply to the start of the image display, as compared with the case where the output of the broadcast signal to the display cannot be started until reconfiguration of the second reconfigurable circuit is completed.

### BRIEF DESCRIPTION OF DRAWINGS

FIG. 1 is a functional block diagram showing a video camera that includes a signal processing device 1000.

FIG. 2 is a flowchart showing the control procedure performed by a control unit 130.

FIG. 3 is a flowchart showing the control procedure performed by a control unit 230.

FIG. 4 is a timing chart showing the operations by reconfigurable arrays A-H.

FIG. 5 is a functional block diagram showing a mobile phone that includes a signal processing device 1100.

FIG. 6 is a functional block diagram showing a television receiver that includes a signal processing device 1200.

FIG. 7 is a functional block diagram showing a hard disk recorder that includes a signal processing device 1300.

FIG. 8 is a functional block diagram showing a television receiver that includes a signal processing device 2000.

FIG. 9 is a flowchart showing the control procedures one performed by a control unit 320 and the other by a reconfigurable array α having been reconfigured based on configuration information sq.

### DESCRIPTION OF EMBODIMENTS

The following describes one embodiment of a signal processing device according to the present invention, with reference to the accompanying drawings.

### Embodiment

### Structure

First, the following describes the structure of a signal processing device 1000 consistent with this embodiment.

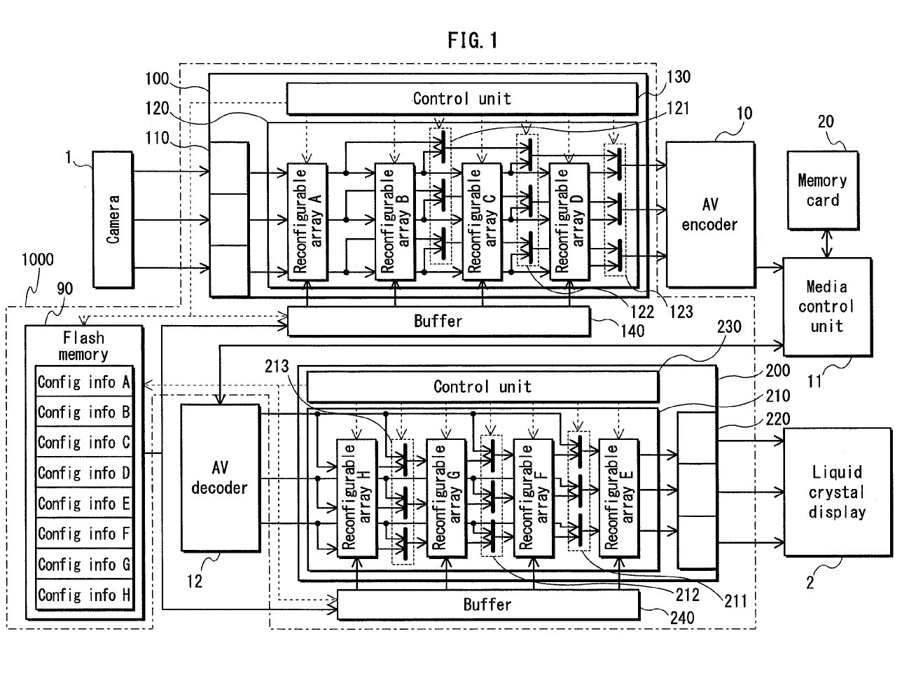

FIG. 1 is a functional block diagram showing a video camera that includes the signal processing device 1000.

As shown in the figure, the signal processing device 1000 is connected to a camera 1 and a liquid crystal display 2 each of which is an external device and also connected to an AV encoder 10 and an AV decoder 12 each of which is an internal device. The signal processing device 1000 includes flash memory 90, a reconfigurable input unit 100, a buffer 140, a reconfigurable output unit 200, and a buffer 240.

In the example described below, the signal processing device 1000 is connected to the camera 1 and the liquid crystal display 2 to constitute a video camera. Yet, the signal processing device 1000 includes reconfigurable circuits as will be later described and thus may be connected to a camera and a display other than the camera 1 and the liquid crystal display 2 or to an external device other than a camera or a display to constitute a various different device.

Note in the description below, the reconfigurable input unit 100 and the reconfigurable output unit 200 are implemented by a single LSI. Alternatively, however, the respective units 100 and 200 may be implemented by separate LSIs.

The following now describes components connected to the signal processing device 1000.

The camera 1 sequentially capture consecutive images at a constant frame rate (for example, 30 fps (frame per second)) and input a resultant image signal to the reconfigurable input unit 100. In one example described below, the image signal is composed of R (Red), G (Green), and B (Blue) signals each of which is composed of 8 bits.

The liquid crystal display 2 displays images based on an image signal in a supported format. In one example described below, the liquid crystal display 2 supports the format of image signal composed of R, G and B signals each of which is composed of 8 bits. In the description below, each of R, G and B signals is superimposed with a synchronous signal.

The AV encoder 10 applies a compression coding process according to the MPEG (Moving Picture Experts Group) standard to an image signal in the supported format, and outputs resultant compressed data to a media control unit 11. In one example described below, the signal format supported by the AV encoder 10 is an image signal composed of a Y (luminance) signal, a U (color difference, B-Y) signal, and a V (color difference, R-Y) signal each of which is composed of 8 bits.

The media control unit 11 stores the compressed data received from the AV encoder 10 into a memory card 20. In response to a request from the AV decoder 12, the media control unit 11 reads compressed data from the memory card 20 and outputs the read compressed data to the AV decoder 12.

The AV decoder 12 decodes, according to the MPEG standard, the compressed data received from the media control unit 11 and outputs the decoded image signal (signal in YUV format) to the reconfigurable output unit 200.

The following now describes each component of the signal processing device 1000.

The flash memory 90 stores pieces of configuration information (A-H) which is for reconfiguring the reconfigurable input unit 100 or the reconfigurable output unit 200 into a circuit that performs a desired image process (in the figures, each piece of configuration information may be abbreviated as “config info” for the sake of convenience). Each piece of configuration information is about hundreds of bytes in size.

The reconfigurable input unit 100 includes an input unit 110, a reconfigurable array unit 120, and a control unit 130. Based on configuration information, the circuit configuration of the reconfigurable array unit 120 is altered, so that the reconfigurable input unit 100 becomes able to output to the AV encoder 10 a signal that is obtained by conducting one or more predetermined processes on the image signal input from the camera 1.

The input unit 110 is an interface connecting the camera 1 to the reconfigurable input unit 100 and transmits an image signal (signal in RGB format) fed from the camera 1 to the reconfigurable array unit 120.

The reconfigurable array unit 120 includes reconfigurable arrays A-D and selectors 121-123.

By feeding one of the pieces of configuration information read from the flash memory 90 and stored in the buffer 140, each of the reconfigurable arrays (A-D) acts as a circuit that conducts a predetermined process on a received image signal and outputs the processed image signal. Each reconfigurable array is implemented by a reconfigurable circuit such as PLD or FPGA.

Each of the selectors (121-123) selectively outputs either of a signal before or after the process (i.e., a signal processed or not processed) by a preceding (i.e., upstream) one of the reconfigurable arrays (B-D). Note that the selection of a signal to be output is made under the control by the control unit 130. As shown in the figure, the selectors 121 and 122 output the selected signals to the selectors 122 and 123, respectively. The selector 123 outputs the selected signal to the AV encoder 10. In the initial state (immediately after the power supply to the signal processing device 1000 is started), each selector is controlled by the control unit 130 to select a signal before the process by a preceding one of the reconfigurable circuits (B-D).

The following specifically describes the functions of the individual reconfigurable arrays.

Being fed with the configuration information A, the reconfigurable array A acts as a circuit that conducts “Process A” and outputs a signal resulting from Process A (i.e., post-Process A signal). Note that Process A is to convert an image signal fed from the camera 1 via the input unit 110 (i.e., signal in RGB format) into the format supported by the AV encoder 10 (i.e., signal in YUV format).

An image signal in the format supported by the AV encoder 10 means a YUV signal. That is, Process A is an essential process for allowing the AV encoder 10 to process the image signal received from the camera 1.

Being fed with the configuration information B, the reconfigurable array B acts as a circuit that conducts “Process B” and outputs an image signal resulting from Process B (i.e., post-Process B image signal). Note that Process B is to correct defective pixels possibly present in the post-Process A signal that is output from the reconfigurable array A.

Being fed with the configuration information C, the reconfigurable array C acts as a circuit that conducts “Process C” and outputs an image signal resulting from Process C (i.e., post-Process C image signal). Note that Process C is to adjust the contrast and brightness of the post-Process B image signal that is output from the reconfigurable array B.

Being fed with the configuration information D, the reconfigurable array D acts as a circuit that conducts “Process D” and outputs an image signal resulting from Process D (i.e., post-Process D signal). Note that Process D is to adjust the chrominance of the post-Process C image signal that is output from the reconfigurable array C.

Processes B-D described above are a series of image correction processes conducted to improve the quality of image signal fed from the camera 1. That is, the AV encoder 10 is able to conduct the compression coding process on the image signal supplied from the camera 1, without requiring Processes B-D to be conducted. In this sense, Processes B-D may be said additional processes.

It is generally true that images captured by one camera tend to be brighter than images captured by another camera, even if the cameras are used in the same environment. More specifically, the properties such as contrast, brightness and chrominance of images taken by different cameras show different characteristics specific to the type of camera used. For this reason, the details of Processes C and D are set to correct the properties such as contrast of images fed from the camera 1 to meet the predetermined standard. The pieces of configuration information (A-D) are defined by the manufacturers of video cameras, etc. to realize Processes A-D and stored in the flash memory 90.

The control unit 130 feeds the pieces of configuration information A-D stored in to the flash memory 90 to the reconfigurable arrays and controls the switching of signals to be selected by the selectors. This function of signal switching is implemented by a programmed circuit (processor). Note that the control unit 130 also stores the sizes of the pieces of configuration information (A-D).

The buffer 140 is connected to each of the reconfigurable arrays (A-D) as well as to the flash memory 90 and used to temporarily store the pieces of configuration information A-D read by the control unit 130 from the flash memory 90 and feeds a specific piece of configuration information to a specific one of the reconfigurable arrays according to instructions given by the control unit 130. The buffer 140 is provided to compensate the difference between (i) the data width between the flash memory 90 and the buffer 140 (e.g., 8 bits) and (ii) the data width between the buffer 140 and each of the reconfigurable arrays (A-D)(e.g., 1 bit).

The reconfigurable output unit 200 includes a reconfigurable array unit 210, an output unit 220, and a control unit 230. Based on the configuration information stored in the flash memory 90, the circuit configuration of the reconfigurable array unit 210 is altered, so that the reconfigurable output unit 200 becomes able to output to the liquid crystal display 2 an image signal that is obtained by conducting one or more predetermined processes on the decoded image signal (signal in YUV format) received from the AV decoder 12.

The reconfigurable array unit 210 includes reconfigurable arrays E-H and selectors 211-213. The reconfigurable arrays E-H are basically similar to the reconfigurable arrays A-D, whereas the selectors 211-213 are basically similar to the selectors 121-123. Therefore, the following mainly describes the differences.

Similarly to the selectors 121-123, each of the selectors 211-213 selectively outputs one of the two signals under control of the control unit 230. Yet, the selectors 211-213 are different from the selectors 121-123 in that each of the selectors 211-213 selects either the image signal fed from the AV decoder 12 or the signal processed by a preceding one of the reconfigurable arrays (H-F) and outputs the selected signal to the succeeding (i.e., downstream) one of the reconfigurable arrays (G-E). In the initial state (immediately after the power supply to the signal processing device 1000 is started), each selector is controlled by the control unit 230 to select the image signal fed from the AV decoder 12.

The following specifically describes the functions of the individual reconfigurable arrays (E-H).

Being fed with the configuration information E, the reconfigurable array E acts as a circuit that conducts “Process E” and outputs a signal resulting from Process E (i.e., post-Process E signal). Note that Process E is to convert an image signal fed from the selector 211 (signal in YUV format) into the format supported by the liquid crystal display 2 (i.e., RGB signal superimposed with synchronous signals).

An image signal in the format supported by the liquid crystal display 2 means an image signal RGB signal superimposed with synchronous signals. That is, Process E is an essential process for allowing the liquid crystal display 2 to display images based on the image signal (signal in YUV format) received from the AV decoder 12.

Being fed with the configuration information F, the reconfigurable array F acts as a circuit that conducts “Process F” on the image signal fed from the selector 212 and outputs an image a signal resulting from Process F (i.e., post-Process F image signal) to the selector 211. Note that Process F is to adjust the brightness of the received image signal.

Being fed with the configuration information G, the reconfigurable array G acts as a circuit that conducts “Process G” on an image signal supplied from the selector 213 and outputs an image resulting from Process G (i.e., post-Process G signal). Note that Process G is to adjust the contrast of the received image signal.

Being fed with the configuration information H, the reconfigurable array H acts as a circuit that conducts “Process H” on a decoded image signal fed from the AV decoder 12 and outputs an image signal resulting from Process H (i.e., post-Process H signal) to the selector 213. Note that Process H is to adjust the chrominance of the received image signal.

Processes F-H described above are a series of image correction processes conducted to improve the quality of image signal fed from the AV decoder 12. In this sense, Processes F-H may be said additional processes, similarly to Processes B-D.

As with cameras, it is generally true that images presented by one display tend to be brighter than images presented by another display, even if the image signal is the same. More specifically, the properties such contrast, brightness, and chrominance of images presented by different displays show different characteristics specific to the type of display used.

For this reason, the details of Processes F-H are set to correct the properties, such as contrast, brightness and chrominance of images presented on the liquid crystal display 2 to meet the predetermined standard. As described above, the image signal fed from the camera 1 have been corrected through Processes C and D to meet the predetermined standard. In view of this, the details of Processes F-H are determined so that images displayed maintain the standardized properties. The pieces of configuration information (E-H) are defined by the manufacturers of video cameras, etc. to realize Processes E-H and stored in the flash memory 90.

The output unit 220 is an interface for connecting the reconfigurable output unit 200 and the liquid crystal display 2. The output unit 220 transmits the image signal (RGB signal superimposed with synchronous signals) fed from the reconfigurable output unit 200 to the liquid crystal display 2.

Similarly to the control unit 130, the control unit 230 feeds the pieces of configuration information (E-H) to the reconfigurable arrays (E-H) and also controls the switching of signals to be selected by the selectors (211-213).

Similarly to the buffer 140, the buffer 240 is used to temporarily store the pieces of configuration information E-H read by the control unit 230 from the flash memory 90 and feeds a specific piece of configuration information to a specific one of the reconfigurable arrays according to instructions given by the control unit 230. The description of the data width given in relation to the buffer 140 is applicable to the data width between the flash memory 90 and each of the reconfigurable arrays (E-H).

Although not specifically shown in FIG. 1, when reading configuration information from the flash memory 90 to a corresponding one of the buffers (140 and 240), the control units 130 and 230 exchange notifications to establish synchronization to avoid access contention. A detailed description there of will be given below.

### <Operation>

The following now describes the operation of the signal processing device 1000 having the structure described above.

### <Control Unit 130>

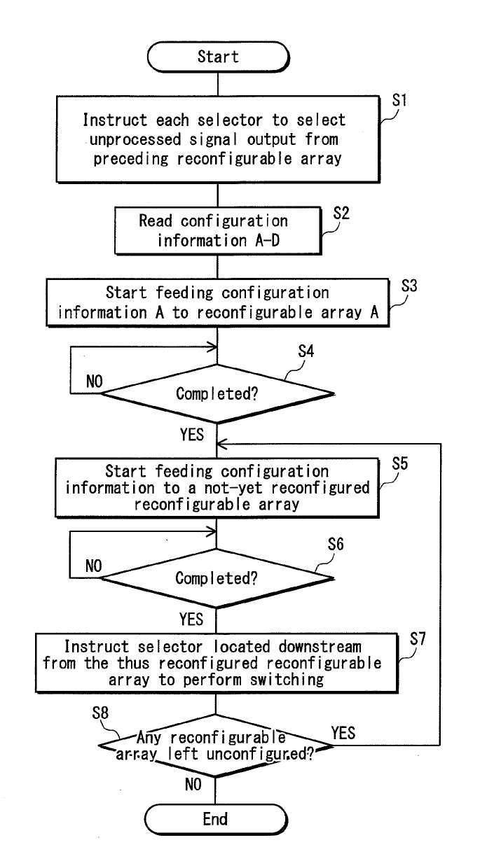

FIG. 2 is a flowchart showing the control procedure performed by the control unit 130.

The following describes the operation of the control unit 130 with reference to FIG. 2.

Upon the start of power supply to the signal processing device 1000, the control unit 130 controls the selectors (121-123) included in the reconfigurable array unit 120 to select a signal not yet processed by a preceding one of the reconfigurable arrays (B-D) (Step S1).

In addition, the control unit 130 sequentially reads the pieces of configuration information A-D from the flash memory 90 into the buffer 140 (Step S2), and then starts feeding the read configuration information A to the reconfigurable array A from the buffer 140 (Step S3). Upon completion of the reading of one piece of configuration information to the buffer 140, the control unit 130 issues to the control unit 230 a read-completion notification indicating that the reading of a piece of configuration information is completed, and waits to read the next piece of configuration information until a read-completion notification is received from the control unit 230. In this way, the control unit 130 establishes synchronization with the control unit 230, so that contention for access to the flash memory 90 is avoided.

The control unit 130 judges whether or not the reconfiguration of the reconfigurable array A is completed, based on whether or not the amount of data fed to the reconfigurable array A has reached the size of configuration information A stored in advance (Step S4). If the reading is not completed yet (Step S4: NO), Step S4 is repeated. If the reading is completed (Step S4: YES), the control unit 130 starts feeding the next piece of configuration information from the buffer 140 to a corresponding reconfigurable array which has not been reconfigured yet (Step S5).

The control unit 130 repeats Step S5 to cause the reconfiguration of the reconfigurable arrays B, C, and D in the stated order. That is, in the first iteration of Step S5, the configuration information B is started to be fed to the reconfigurable array B.

In a manner similar to Step S4 described above, the control unit 130 judges whether or not reconfiguration of a reconfigurable array received the piece of configuration information started to be fed in Step S5 is completed (Step S6). If the reconfiguration is not completed yet (Step S6: NO), Step S6 is repeated. If the reconfiguration is completed (Step S6: YES), the selector succeeding the reconfigurable array having been reconfigured is controlled to select the signal having been processed by that reconfigurable array (Step S7).

That is, in the first iteration of Step S7, the selector 121 is controlled to select the signal having been processed by the reconfigurable array B. In the next iteration of Step S7, the selector 122 is controlled to select the signal having been processed by the reconfigurable array C. In the last iteration of Step S7, the selector 123 is controlled to select the signal having been processed by the reconfigurable array D.

Next, the control unit 130 judges whether or not there is any reconfigurable array which is not yet reconfigured (Step S8). If any reconfigurable array is not yet reconfigured (Step S8: YES), Step S5 and the subsequent steps are repeated. If no reconfigurable array is left without being reconfigured (Step S8: NO), the control procedure is ended.

### <Control Unit 230>

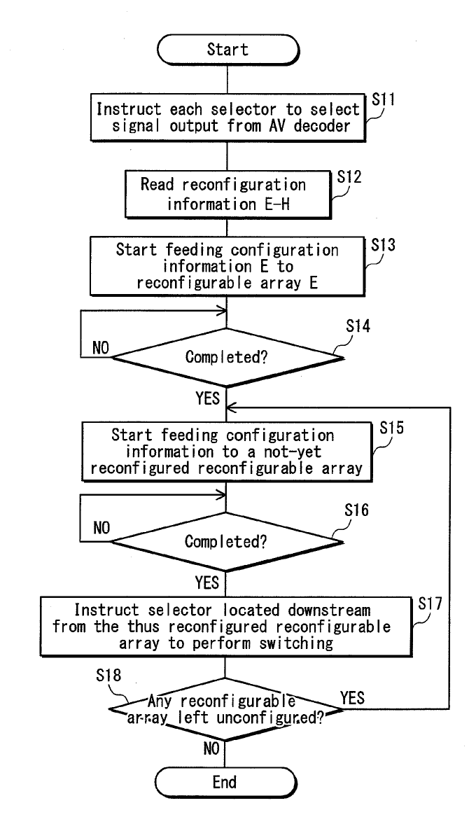

FIG. 3 is a flowchart showing the control procedure performed by the control unit 230.

The following describes the operation of the control unit 230, with reference to FIG. 3. Note that the description is given only briefly, because the operation of the control unit 230 is basically similar to the operation of the control unit 130 described above.

Upon the start of power supply to the signal processing device 1000, the control unit 230 controls the selectors (211-213) included in the reconfigurable array unit 210 to select a signal fed from the AV decoder 12 (Step S11).

In addition, the control unit 230 sequentially reads the pieces of configuration information E-H from the flash memory 90 into the buffer 240 (Step S12), and then starts feeding the read configuration information E to the reconfigurable array E from the buffer 240 (Step S13). In order to establish the synchronization with the control unit 130 described above, the control unit 230 starts the reading of one piece of configuration information to the buffer 240, upon receipt of a read-completion notification from the control unit 130. Then, upon completion of the reading of the piece of configuration information, the control unit 230 issues a read-completion notification to the control unit 130 and waits to read the next piece of configuration information until a read-completion notification is received from the control unit 130.

In a manner similar to Step S4, the control unit 230 judges whether or not reconfiguration of the reconfigurable array E is completed (Step S14). If the reconfiguration is not completed yet (Step S14: NO), Step S14 is repeated. If the reconfiguration is completed (Step S14: YES), the control unit 230 starts feeding the next piece of configuration information the buffer 240 to a corresponding reconfigurable array which has not been reconfigured yet (Step S15). Note that the control unit 230 causes the reconfiguration of the reconfigurable arrays F, G, and H in the stated order.

In a manner similar to Step S14 described above, the control unit 230 judges whether or not reconfiguration of a reconfigurable array received the piece of configuration information started to be fed in Step S15 is completed (Step S16). If the reconfiguration is not completed yet (Step S16: NO), Step S16 is repeated. If the reconfiguration is completed (Step S16: YES), the control unit 230 controls the selector succeeding the reconfigurable array having been reconfigured, to select the signal having been processed by that reconfigurable array (Step S17).

That is, in the first iteration of Step S17, the selector 211 is controlled to select the signal having been processed by the reconfigurable array F. In the next iteration of Step S17, the selector 212 is controlled to select the signal having been processed by the reconfigurable array G. In the last iteration of Step S17, the selector 213 is controlled to select the signal having been processed by the reconfigurable array H.

Next, the control unit 230 judges whether or not there is any reconfigurable array which is not yet reconfigured (Step S18). If any reconfigurable array is not yet reconfigured (Step S18: YES), Step S15 and the subsequent steps are repeated. If no reconfigurable array is left without being reconfigured (Step S18: NO), the control procedure is ended.

### <Individual Reconfigurable Arrays>

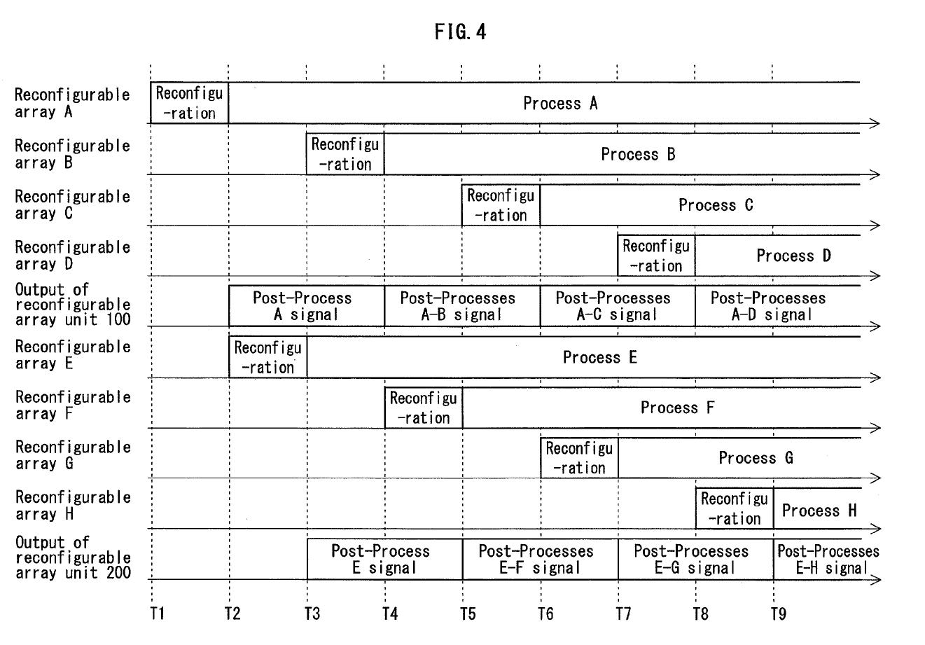

FIG. 4 is a timing chart showing the operations by the reconfigurable arrays A-H.

The following describes the operations of the individual reconfigurable arrays, with reference to the figure.

At a temporal point T1 shown in the figure, the power supply to the signal processing device 1000 starts, and the control unit 130 starts feeding the configuration information A from the buffer 140 to the reconfigurable array A. Note that as of the temporal point T1, each of the selectors 121-123 is controlled by the control unit 130 to select a signal not yet processed by a preceding one of the reconfigurable arrays (B-D).

At a temporal point T2, the feeding of the configuration information A to the reconfigurable array A is completed, the reconfigurable array A starts conducting Process A, and the control unit 230 starts feeding the configuration information E from the buffer 240 to the reconfigurable array E. Note that as of the temporal point T2, each of the selectors 211-213 is controlled by the control unit 230 to select an image signal fed from the AV decoder 12.

Since the reconfigurable array A starts to conduct Process A at the temporal point T2, the reconfigurable input unit 100 starts to output the post-Process A signal. More specifically, the output signal is the one obtained by simply converting the image signal (signal in RGB format) fed from the camera 1 into the YUV format supported by the AV encoder 10. Consequently, the AV encoder 10 is enabled to start the compression coding at the temporal point T2.

At a temporal point T3, the feeding of the configuration information E to the reconfigurable array E is completed, the reconfigurable array E starts to conduct Process E, and the control unit 130 starts to feed the configuration information B from the buffer 140 to the reconfigurable array B.

Since the reconfigurable array E starts to conduct Process E at the temporal point T3, the reconfigurable output unit 200 starts to output the post-Process E signal. More specifically, the output signal is the one obtained by simply converging the image signal (signal in YUV format) fed from the AV decoder 12 into an RGB signal superposed with synchronous signals. That is, the output signal is in the format supported by the liquid crystal display 2. Consequently, the liquid crystal display 2 is enabled to start displaying images at the temporal point T3.

At a temporal point T4, the feeding of the configuration information B to the reconfigurable array B is completed, the reconfigurable array B starts to conduct Process B, and the control unit 230 starts to feed the configuration information F from the buffer 240 to the reconfigurable array F. As of the temporal point T4, the selector 121 is controlled by the control unit 130 to select a signal having been processed by the reconfigurable array B.

Since the reconfigurable array B starts to conduct Process B at the temporal point T4, the reconfigurable input unit 100 starts to output the post-Processes A and B signal. More specifically, the output signal is the one obtained by correcting defective signals possibly present in the post-Process A signal. Consequently, as of the temporal point T4, the AV encoder 10 is enabled to perform compression coding on the image signal having been corrected for defective pixels.

At a temporal point T5, the feeding of the configuration information F to the reconfigurable array F is completed, the reconfigurable array F starts to conduct Process F, and the control unit 130 starts to feed the configuration information C from the buffer 140 to the reconfigurable array C. Note that as of the temporal point T5, the selectors 211 is controlled by the control unit 230 to select an image signal having been processed by the reconfigurable array F.

Since the reconfigurable array F starts to conduct Process F as of the temporal point T5, the reconfigurable output unit 200 outputs the post-Processes E and F signal. More specifically, the output signal is the one obtained by correcting the brightness of the post-Process E signal. Consequently, at the temporal point T5, the liquid crystal display 2 is enabled to start presenting images based on the image signal having been corrected for the brightness.

Similarly, at a temporal point T6, the reconfigurable array C starts to conduct Process C, and the configuration information G is started to be fed to the reconfigurable array G. At a temporal point T7, the reconfigurable array G starts to conduct Process G, and the configuration information D is started to be fed to the reconfigurable array D. At a temporal point T8, the reconfigurable array D starts to conduct Process D, the configuration information H is started to be fed to the reconfigurable array H. At a temporal point T9, the reconfigurable array H starts to conduct Process H.

As a result, at the temporal point T6, the AV encoder 10 is enabled to perform the compression coding on the image signal having been further corrected for the contrast and brightness. At the temporal point T8, the AV encoder 10 is enabled to perform the compression coding on the image signal having been further corrected for the chrominance.

At the temporal point T7, the liquid crystal display 2 is enabled to display images based on the image signal having been further corrected for the contrast. At the temporal point T9, the liquid crystal display 2 is enabled to display images based on the image signal having been further corrected for the chrominance.

As described above, the AV encoder 10 is enabled to start the compression coding as soon as the reconfigurable array A that conducts Process A is reconfigured (i.e., at the temporal point T2), without waiting for the reconfiguration of the reconfigurable arrays B-D that conduct Processes B-D. Similarly, the liquid crystal display 2 is enabled to start the image display as soon as the reconfigurable array E that conducts Process E is reconfigured (i.e., at the temporal point T3), without waiting for reconfiguration of the reconfigurable arrays F-H that conduct Processes F-H. In this manner, the signal processing device 1000 manages to reduce the startup time, which is the time taken from the start of power supply and the start of processing.

Furthermore, the AV encoder 10 is enabled to perform compression coding on images of the quality improved in stages with the passage of time from the start of the power supply to the signal processing device 1000. Similarly, the liquid crystal display 2 is enabled to present images of the quality improved in stages with the passage of time.

### <Other Applications>

The embodiment described above is directed to an example in which the signal processing device 1000 is connected to the camera 1 and the liquid crystal display 2 to constitute a video camera. The following briefly describes other exemplary applications in which the signal processing device 1000 is connected to different external devices to constitute different devices or appliances.

### <Mobile Phone>

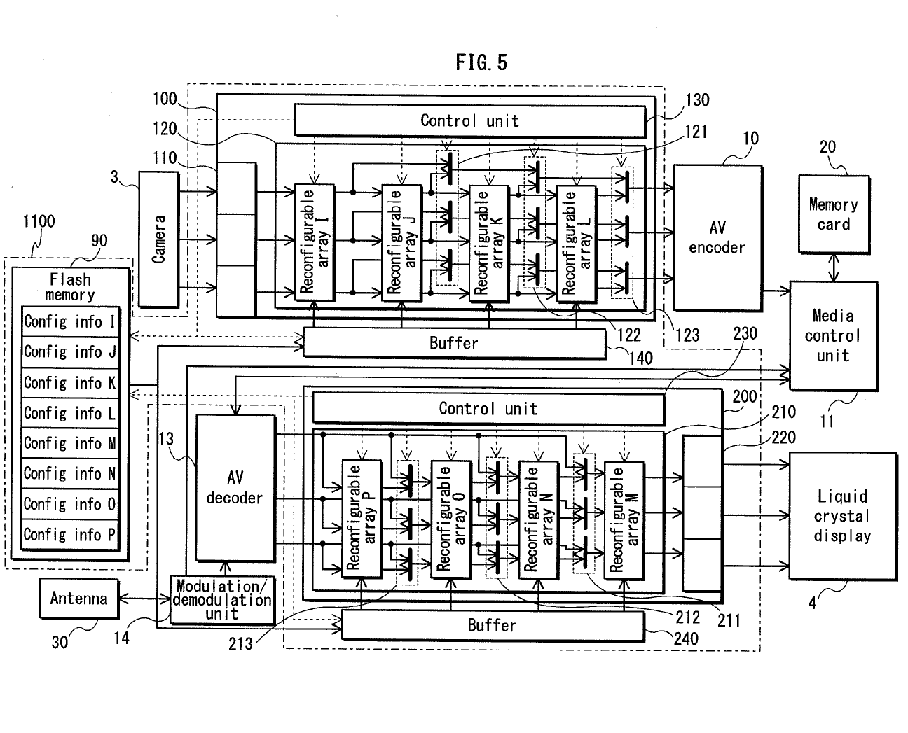

FIG. 5 is a functional block diagram showing a mobile phone that includes a signal processing device 1100.

As shown in the figure, the signal processing device 1100 is connected to a camera 3 and a liquid crystal display 4, each of which is an external device, and also connected to the AV encoder 10 and an AV decoder 13, each of which is an internal device. Basically, the signal processing device 1100 includes the same components as the signal processing device 1000.

Note that the reconfigurable arrays I-P shown in the figure are the same as the reconfigurable arrays A-H consistent with the above-described embodiment. The reconfigurable arrays I, J, K, and L are reconfigured in the stated order, by being sequentially fed with a corresponding one of the pieces of configuration information I, J, K, and L. Similarly, the reconfigurable arrays M, N, O, and P are sequentially reconfigured in the stated order, by being fed with a corresponding piece of configuration information M, N, O, and P.

Note that the functions performed by the reconfigurable arrays I-P after reconfiguration are basically the same as the functions performed by the reconfigurable arrays A-H after reconfiguration. Yet, the signal processing device 1100 is different from the signal processing device 1000 with respect to the external devices connected thereto. Naturally, the processes conducted by the reconfigurable arrays I-P having been reconfigured may be made to slightly differ from the processes conducted by the reconfigurable arrays A-H having been reconfigured, in view of the specific characteristics shown by the properties of images taken by the camera 3 or displayed by the liquid crystal display 4.

In addition, unlike the AV decoder 12 described in the above embodiment, the AV decoder 13 is capable of decoding video data (compressed data according to an MPEG standard) that is received via an antenna 30 and a modulation/demodulation unit 14.

Consequently, the signal processing device 1100 outputs, to the liquid crystal display 4, an image signal at the quality improved in stages, depending on which of the reconfigurable arrays M-P have been reconfigured. More specifically, the image signal initially output is the one obtained by simply converting the decoded video data (signal in YUV format) into an RGB signal superimposed with synchronous signals. The image signal subsequently output is improved in quality by correcting the brightness, contrast, and chrominance in stages.

### <Television Receiver>

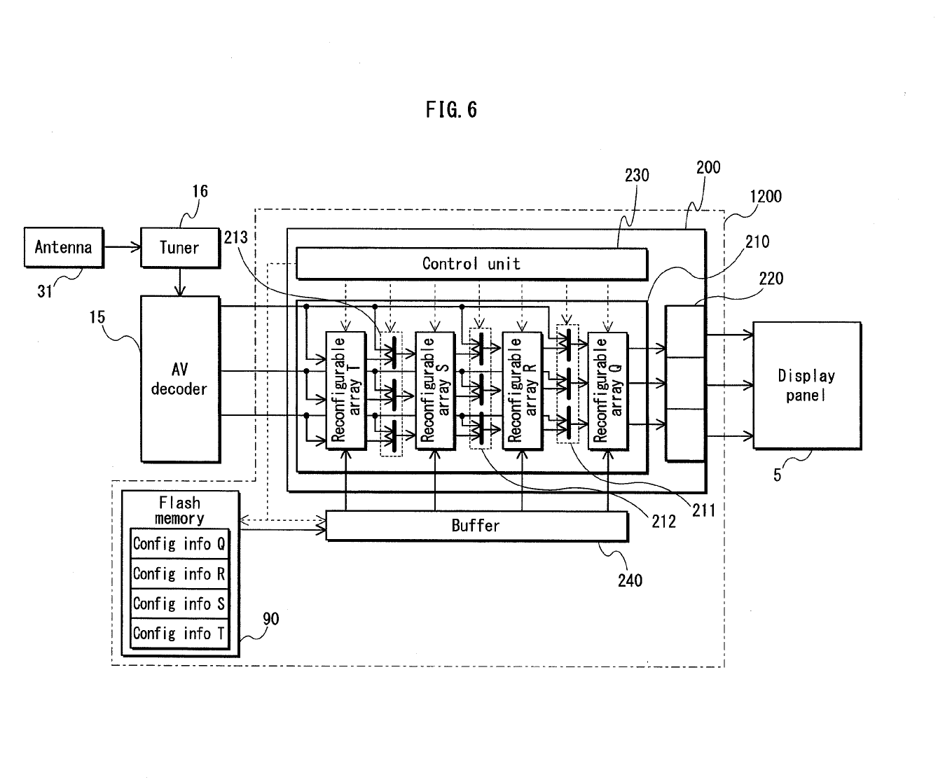

FIG. 6 is a functional block diagram showing a television receiver that includes a signal processing device 1200.

As shown in the figure, the signal processing device 1200 is connected to a display panel 5 which is an external device and also connected to an AV decoder 15 which is an internal device. The signal processing device 1200 includes the flash memory 90, the reconfigurable output unit 200, and the buffer 240 all of which are described in the above embodiment. The flash memory 90 stores pieces of configuration information Q-T.

Note that the reconfigurable arrays Q-T shown in the figure are the same as the reconfigurable arrays E-H consistent with the above-described embodiment. The reconfigurable arrays Q, R, S, and T are reconfigured in the stated order by being sequentially fed with a corresponding one of the pieces of configuration information Q, R, S, and T.

Unlike the signal processing device 1000, the signal processing device 1200 does not have a reconfigurable input unit. Therefore, the control unit 230 can read configuration information from the flash memory 90 into the buffer 240, without the need to establish synchronization with another control unit.

Similarly to the reconfigurable array E described in the above embodiment, the reconfigurable array Q having been reconfigured converts the signal format. Yet, the difference with the reconfigurable array E lies in that the reconfigurable array Q having been reconfigured converts a signal in YUV444 format, which is a signal containing the Y, U, V components at the rate of 4:4:4, into a signal in RGB format superimposed with synchronous signals.

In addition, since the signal processing device 1200 is connected to a different external device from the external device connected to the signal processing device 1000, the processes conducted by the reconfigurable arrays R-T having been reconfigured may be made to slightly differ from the processes conducted by the reconfigurable arrays F-H having been reconfigured for the following reason described above.

Further, unlike the AV decoder 12 described in the above embodiment, the AV decoder 15 decodes digital broadcast data received via an antenna 31 and a tuner 16.

Consequently, the signal processing device 1200 outputs, to the display panel 5, an image signal at the quality improved in stages, depending on which of the reconfigurable arrays Q-T have been reconfigured. More specifically, the image signal initially output is the one obtained by simply converting the decoded digital broadcast data (signal in YUV444 format) into an RGB signal superimposed with synchronous signals. The image signal sequentially output is improved in quality by correcting the contrast, brightness, and chrominance in stages.

### <Hard Disk Recorder>

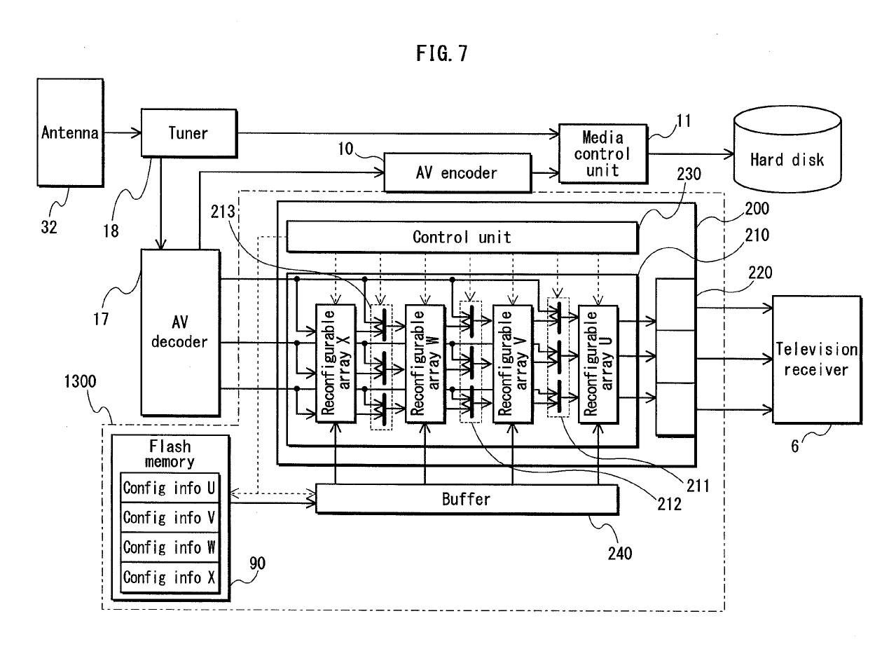

FIG. 7 is a functional block diagram showing a hard disk recorder that includes a signal processing device 1300.

As shown in the figure, the signal processing device 1300 is connected to a television receiver 6 which is an external device, and also connected to an AV decoder 17 which is an internal device. The signal processing device 1300 includes the flash memory 90, the reconfigurable output unit 200, and the buffer 240 all of which are described in the above embodiment.

Note that the reconfigurable arrays U-X shown in the figure are the same as the reconfigurable arrays E-H consistent with the above-described embodiment. The reconfigurable arrays U, V, W and X are reconfigured in the stated order by being sequentially fed with a corresponding one of the pieces of configuration information U, V, W, and X. Similarly to the signal processing device 1200 described above, the control unit 230 can read configuration information without the need to establish synchronization with another control unit.

Similarly to the reconfigurable array E described in the above embodiment, the reconfigurable array U having been reconfigured converts the signal format. Yet, the difference with the reconfigurable array E lies in that the reconfigurable array U having been reconfigured converts a signal in YUV420 format, which is a signal containing the Y, U, V components at the rate of 4:2:0, into an S-video (Separate video) signal composed of a Y signal and a C (color) signal.

No detailed description is given of the processes conducted by the reconfigurable arrays V-X having been reconfigured. Yet, all the processes are to correct an image signal to improve the quality of resultant images, in view of the image properties, such as contrast, showing the characteristics specific to the television receiver 6, which is an external device.

Further, unlike the AV decoder 12 described in the above embodiment, the AV decoder 17 decodes a digital television broadcast signal received via the antenna 31 and the tuner 16.

Consequently, the signal processing device 1300 outputs, to the television receiver 6, an image signal at the quality improved in stages, depending on which of the reconfigurable arrays U-X have been reconfigured. More specifically, the signal initially output is the S-video signal obtained by simply converting the format of the decoded television broadcast signal (signal in YUV420 format). The S-vide signal subsequently output is improved in quality by correcting the contrast, brightness, and chrominance in stages.

### <<Modifications>>

In the embodiment described above, the reconfigurable array units (120 and 210) each include four reconfigurable arrays. However, depending on the processing performed by the signal processing device, it may be necessary to employ a greater number of reconfigurable arrays.

Such a modification leads to increase the total size of pieces of configuration information stored in the flash memory 90. In view of this, a modification described bellow is directed to a signal processing device in which one or more of the plurality of pieces of configuration information stored in the flash memory 90 is in a compressed stated. Each piece of compressed configuration information is decompressed before being fed to a reconfigurable array for reconfiguration.

In one example described below, the signal processing device according to this modification is connected to a display panel, which is an external device, to constitute a television receiver. The following description focuses on differences with the television receiver that includes the signal processing device 1200 and that is described with reference to FIG. 6.

### <Structure>

First, the following describes a signal processing device 2000 consistent with the modification.

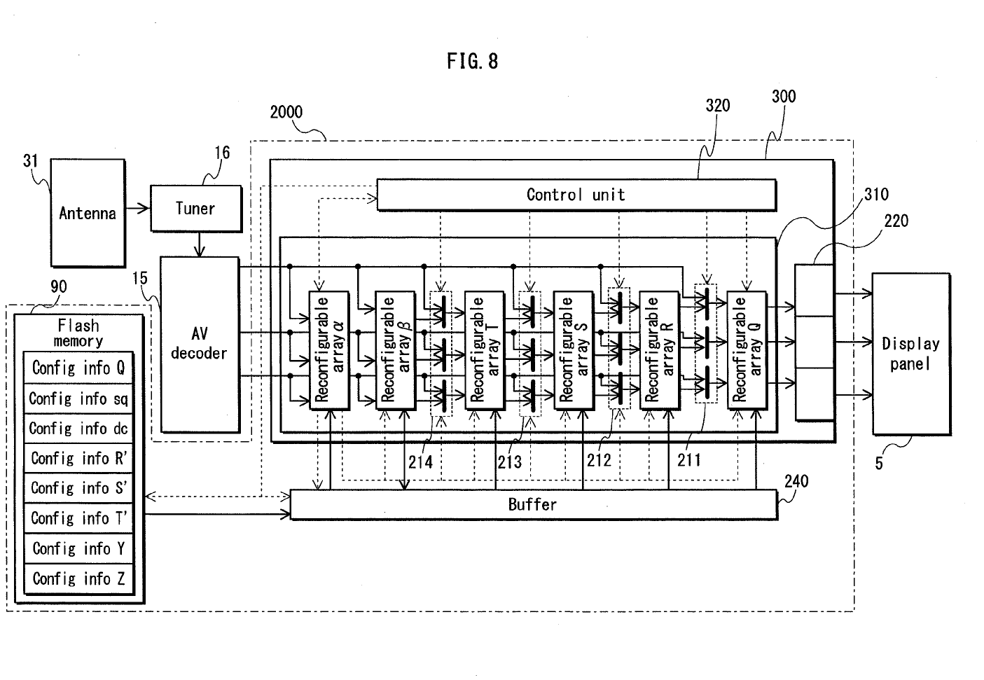

FIG. 8 is a functional block diagram showing the television receiver that includes the signal processing device 2000.

As shown in the figure, the signal processing device 2000 is connected to the display panel 5 which is an external device and the AV decoder 15 which is an internal device. The signal processing device 2000 includes the flash memory 90, a reconfigurable output unit 300, and the buffer 240.

Note that the AV decoder 15, the tuner 16, and the antenna 31 shown in the figure are the same as corresponding components of the television receiver that includes the signal processing device 1200 (see FIG. 6).

Similarly to the above embodiment, the flash memory 90 stores pieces of configuration information (Q, sq, dc, R′-T′, Y and Z). Yet, the difference lies in that the pieces of configuration information R′-T′ stored in the flash memory 90 are generated by compressing pieces of configuration information R-T using an encoding method, such as Huffman coding.

The reconfigurable output unit 300 includes the output unit 220, a reconfigurable array unit 310, and a control unit 320. The output unit 220 is the same as the output unit 220 provided for the reconfigurable array unit 210 included in the signal processing device 1200.

The reconfigurable array unit 310 includes reconfigurable arrays Q-T, α and β and selectors 211-214. The reconfigurable array unit 310 is basically the same as the reconfigurable array unit 210, except for the addition of the reconfigurable arrays α and β and the selector 214.

Being fed with the configuration information sq, the reconfigurable array α acts as a circuit that feeds the configuration information dc to the reconfigurable array β, and controls the switching of a signal to be selected by the selector 214. In addition, this circuit also performs part of the control procedure performed by the control unit 230 provided for the reconfigurable array unit 210.

The part of the control procedure performed by the control unit 230 mentioned above will be described later in detail. Briefly, the reconfigurable array α feeds the pieces of configuration information R-T to the reconfigurable arrays R-T. After completion of the reconfiguration of the reconfigurable arrays R-T, the control unit 230 controls the switching of signals to be selected by the selector 211-213.

Being fed with the configuration information Z, the reconfigurable array α acts as a circuit similar to the reconfigurable arrays R-T having been reconfigured. That is, the reconfigurable array α having been reconfigured conducts an image correction process to improve the received image signal.

Being fed with the configuration information dc, the reconfigurable array β acts as a circuit that sequentially reads the pieces of configuration information R′-T′ from the flash memory 90 into the buffer 240, decompresses the read pieces of configuration information R′-T′ into the pieces of configuration information R-T, and feeds the decompressed pieces of configuration information sequentially to the buffer 240.

Being fed with the configuration information Y, the reconfigurable array β then acts as a circuit similar to the reconfigurable arrays R-T having been reconfigured. That is, the reconfigurable array β having been reconfigured conducts an image correction process to improve the quality of the received image signal.

Since the reconfigurable array α having been reconfigured based on the configuration information sq takes over part of the control procedure performed by the control unit 230, the control unit 320 performs the rest of the control procedure, in addition to the feeding of the pieces of configuration information sq and Z to the reconfigurable array a.

### <Operation>

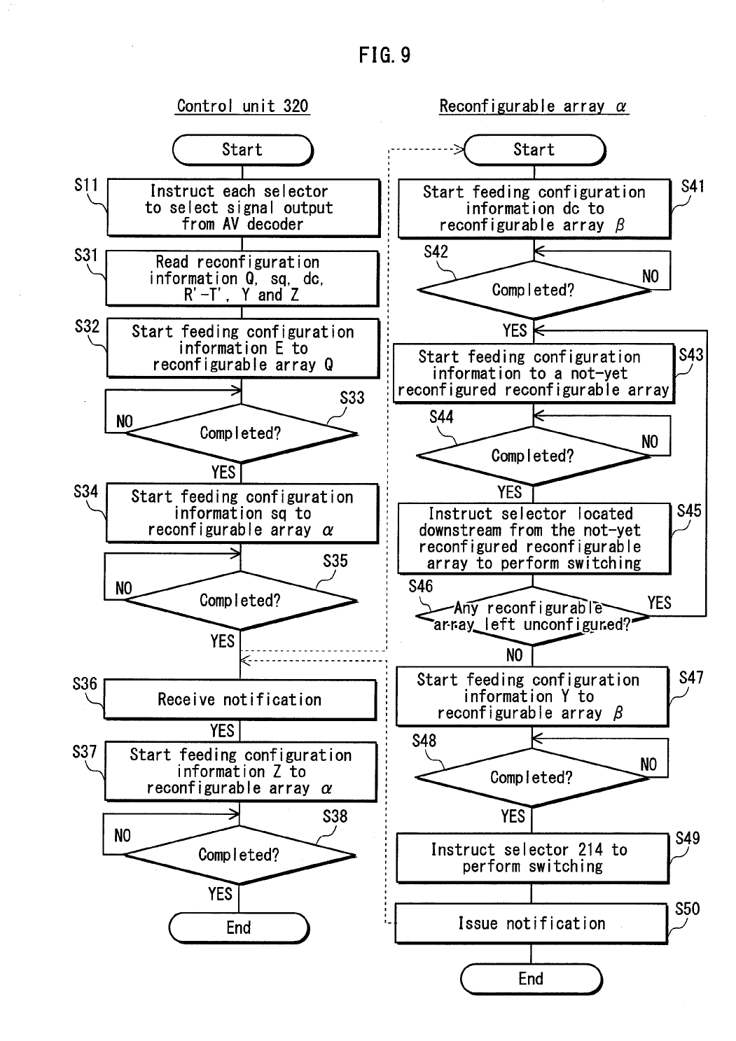

FIG. 9 is a flowchart showing the control procedures one performed by the control unit 320 and the other by the reconfigurable array α having been reconfigured based on the configuration information sq.

With reference to the figure, the following describes the operations of the control unit 320 and the reconfigurable array α.

Upon the start of power supply to the signal processing device 2000, the control unit 320 controls the selectors (211-214) included in the reconfigurable array unit 310 to select a signal supplied from the AV decoder 15 (Step S11 in the flow shown on the left side of the figure). This, step is similar to the step performed by the control unit 230.

In a manner similar to Step S12, the control unit 320 sequentially reads the pieces of configuration information Q, sq, dc, R′-T′, Y, and Z from the flash memory 90 into the buffer 240 (Step S31). Then, the control unit 320 starts to feed the configuration information Q from the buffer 240 to the reconfigurable array Q (Step S32). As is true with the signal processing device 1200, the control unit 320 is not required to establish synchronization with another control unit.

In a manner similar to Step S14, the control unit 320 judges whether or not reconfiguration of the reconfigurable array Q is completed (Step S33). If the reconfiguration is not completed yet (Step S33: NO), Step S33 is repeated. If the reconfiguration is completed (Step S33: YES), the control unit 320 starts to feed the configuration information sq from the buffer 240 to the reconfigurable α (Step S34).

In a manner similar to Step S33, the control unit 320 judges whether or not reconfiguration of the reconfigurable array α is completed (Step S35). If the reconfiguration is not completed yet (Step S35: NO), Step S35 is repeated.

On the other hand, if the reconfiguration of the reconfigurable array α is completed (Step S35: YES), the reconfigurable array α having been reconfigured based on the configuration information sq starts to perform the control procedure (see the flow shown on the right side of the figure).

The reconfigurable array α starts to feed the configuration information dc from the buffer 240 to the reconfigurable array β (Step S41).

In a similar manner to e.g., Step S33 described above, the reconfigurable array α judges whether or not reconfiguration of the reconfigurable array β is completed (Step S42). If the reconfiguration is not completed yet (Step S42: NO), Step S42 is repeated. If the reconfiguration of the reconfigurable array β is completed (Step S42: YES), the reconfigurable array β sequentially reads the pieces of configuration information R′-T′ from the buffer 240, sequentially decompresses the read pieces of configuration information R′-T′ into the pieces of configuration information R-T, and sequentially output the decompressed pieces of configuration information R-T to the buffer 240. Then, the reconfigurable array α starts to sequentially feed the pieces of configuration information R-T from the buffer 240 to a corresponding one of the reconfigurable arrays not yet reconfigured (Step S43). Here, the reconfigurable array a causes the reconfigurable arrays R, S and T to be reconfigured in the stated order.

In a similar manner to Step S42 described above, the reconfigurable array α judges whether or not reconfiguration of a reconfigurable array received the piece of configuration information started to be fed in Step S43 is completed (Step S44). If the reconfiguration is not completed yet (Step S44: NO), Step S44 is repeated. If the reconfiguration is completed (Step S44: YES), the reconfigurable array α controls the selector succeeding the reconfigurable array having been reconfigured to, select the signal having been processed by that reconfigurable array (Step S45).

Next, the reconfigurable array α judges whether any one of the reconfigurable arrays R-T is not yet reconfigured (Step S46). If any of the reconfigurable arrays R-T is not yet reconfigured (Step S46: YES), Step S43 and the subsequent steps are repeated. If none of the reconfigurable arrays R-T is left without being reconfigured (Step S46: NO), the reconfigurable array α to start to feed the configuration information Y from the buffer 240 to the reconfigurable array β (Step S47). With this step, the reconfigurable array β having been finished the decompression of all the pieces of compressed configuration information is reconfigured as a circuit that conducts an image correction process, so that the effective use of the reconfigurable array β is ensured.

In a similar manner to Step S42 described above, the reconfigurable array α judges whether or not reconfiguration of the reconfigurable array β is completed (Step S48). If the reconfiguration is not completed yet (Step S48: NO), Step S48 is repeated. If the reconfiguration is completed (Step S48: YES), the reconfigurable array α controls the selector 214 succeeding the reconfigurable array β to select a signal having been processed by the reconfigurable array β (Step S49).

Then, the reconfigurable array α issues a notification indicating the all the control procedure is done, to the control unit 320 (Step S50) and then ends the control procedure.

Upon receipt of the notification issued in Step S50 (Step S36 of the flow shown on the left side of the figure), the control unit 320 starts feeding the configuration information Z from the buffer 240 to the reconfigurable array α (Step S37). With this step, the reconfigurable array α having been finished all the control procedure is reconfigured as a circuit that conducts an image correction process, so that the effective use of the reconfigurable array α is ensured.

In a similar manner to Step S35 described above, the control unit 320 judges whether or not reconfiguration of the reconfigurable array α is completed (Step S38). If the reconfiguration is not completed yet (Step S38: NO), Step S38 is repeated. If the reconfiguration is completed (Step S38: YES), the control unit 320 ends the control procedure.

### <Supplemental Note>

Up to this point, the signal processing devices according to the present invention have been described by way of the embodiment and modifications directed to applications to various devices and appliances. However, it is naturally appreciated that further or alternative modifications including the following may be made and that the present invention is not limited to the specific signal processing devices described above in the embodiment and modifications.

(1) In the embodiment and modifications, each signal processing device is described to conduct predetermined processes on image signals transmitted to and from one or more external devices, such as a camera and a liquid crystal display. It is naturally appreciated, however, the processes may be conducted on signals other than image signals, depending on the type of an external device connected to the signal processing device. Even in such a case, the description regarding the order of reconfiguration of reconfigurable arrays given in the embodiment and modifications is still true. That is, reconfiguration needs to be started from a reconfigurable array that conducts an essential process for the signal transmission with the connected external device.

(2) According to the embodiment, the number of reconfigurable arrays included in the reconfigurable input unit 100 is equal to the number of reconfigurable arrays included in the reconfigurable output unit 200. However, the respective units may include a mutually different number of reconfigurable arrays. Yet, at least two reconfigurable arrays need to be included in each unit.

(3) The embodiment and modifications describe the processes conducted by the reconfigurable input unit and the reconfigurable output included in the signal processing device unit. Yet, those processes are merely examples. Depending on the type of an external device connected to the signal processing device, the respective units may conduct different processes. As long as reconfiguration is started from a reconfigurable array that conducts an essential process for the signal transmission to and from the connected external device, there is no other restrictions regarding the reconfiguration order of the reconfigurable arrays to be reconfigured. Naturally, however, if one process is dependent on another process, the reconfigurable arrays for conducting those processes need to reconfigured in the required order.

(4) According to the modification described above, the reconfigurable array β reconfigured based on the configuration information dc is the only array that conducts the decompression process of configuration information. Alternatively, however, a plurality of reconfigurable arrays may conduct the decompression process in parallel. With this further modification, the compressed configuration information is decompressed at a higher speed.

The following now describes the further modification by way of an example in which the decompression process is conducted by a new reconfigurable array (hereinafter “reconfigurable array γ”), in addition to the reconfigurable array β described above.

In order to enable the reconfigurable array γ to conduct the decompression process, the reconfigurable array α needs to feed the configuration information dc also to the reconfigurable array γ. In order to achieve this, the flash memory 90 needs to store another piece of configuration information (hereinafter, “configuration information seq”), instead of the configuration information sq consistent with the modification. The configuration information seq is defined to reconfigure the reconfigurable array α as a circuit that feeds the configuration information dc to the reconfigurable array γ, in addition to conducting the process described in the above modification.

The process conducted by the reconfigurable array a reconfigured based on the configuration information seq differs from the process shown on the right side of FIG. 9 in the following points.

That is, additional steps are performed between the completion of feeding the configuration information dc to the reconfigurable array β is completed (Step S42:YES) and the start of feeding the next piece of configuration information to a corresponding reconfigurable array not yet configured (Step S43). In the first one of the additional steps, the configuration information dc is started to be fed to the reconfigurable array γ. In the second one of the additional steps, it is judged whether or not reconfiguration of the reconfigurable array γ is completed. Step 43 described above is performed, if the reconfiguration of the reconfigurable array γ is completed.

Having been reconfigured based on the configuration information dc, the reconfigurable array β starts to decompress the configuration information R′, whereas the reconfigurable array γ starts to decompress the configuration information S′, so that the decompression process is conducted in parallel. Upon completing the decompression of the current piece, each of the reconfigurable arrays β and γ starts to decompress the next piece of configuration information that is not yet decompressed.

Here, when the configuration information Y is started to be fed to the reconfigurable array β (Step S47), a new piece of configuration information may be started to be fed to the reconfigurable array γ, so that the reconfigurable array γ is reconfigured as a circuit that conducts a process other then the decompression process. With this arrangement, each of a plurality of reconfigurable arrays having been completed the decompression process is effectively used.

(5) The modification described above is directed to an example in which the signal processing device 2000 is used in the television receiver. It is naturally appreciated, however, that the signal processing device 2000 may be used in any other device and appliance.

In addition, the signal processing device 2000 is described that the reconfigurable array α reconfigured based on the configuration information sq performs the control procedure shown on the right side of FIG. 9. However, the control procedure may be performed by the control unit 320 not by the reconfigurable array α. In other words, the reconfigurable array unit 310 may be structured without the reconfigurable array α.

(6) Note that the flash memory 90 included in each signal processing device according to the embodiment and the modifications is one example of memory usable in the present invention. For example, memory that is freely writeable and erasable as well as memory that is writable only once, such as ROM (Read Only Memory), is usable in the present invention.

(7) Typically, components of the signal processing devices consistent with the embodiment and modifications described above are embodied as LSI, which is an integrated circuit. Note that such components may be integrated into separate chips or some of all the components may be integrated into a single chip.

Although LSI is specifically mentioned herein, the same may also be referred to as an IC, a system LSI, a super LSI, or an ultra LSI, depending on the packaging density.

Furthermore, if the advance in the field of semiconductor technology or in another technology derived therefrom introduces a new integration technology that replaces the LSI, the new technology may be used to integrate the functional blocks. For example, the application of biotechnology is one possibility.

(8) The input unit 110 and the output unit 220 of each signal processing device consistent with the embodiment and the modifications may be further modified so as not to transmit any signal to or from the external device, until after the first one of the reconfigurable arrays in each of the reconfigurable array units is reconfigured. In addition, each reconfigurable array may be modified so as not to accept any signal, until after reconfiguration of the reconfigurable array is completed.

(9) The first to forth reconfigurable circuits according to the present invention correspond to the reconfigurable arrays included in each reconfigurable array unit consistent with the embodiment and modifications described above. In addition, the selector according to the present invention corresponds to the selectors included in the reconfigurable array units. The memory according to the present invention corresponds to the flash memory 90. The control unit and the second control unit according to the present invention correspond to the control units in the reconfigurable array units.

### INDUSTRIAL APPLICABILITY

The present invention is usable in a signal processing device having reconfigurable circuits and reduces the startup time between the start of power supply and the start of processing.

### REFERENCE SIGNS LIST

1, 3 camera
2, 4 liquid crystal display
5 display panel
6 television receiver
10 AV encoder
11 media control unit
12, 13, 15, 17 AV decoder
14 modulation/demodulation unit
16, 18 tuner
20 memory card
30, 31, 32 antenna
90 flash memory
100 reconfigurable input unit
110 input unit
120, 210, 310 reconfigurable array unit
121-123, 211-214 selector
130, 230, 320 control unit
140, 240 buffer
200, 300 reconfigurable output unit
220 output until
1000, 1100, 1200, 1300, 2000 signal processing device

1. A signal processing device including a first reconfigurable circuit and a second reconfigurable circuit, a logic configuration of each reconfigurable circuit being alterable, and the reconfigurable circuits being sequentially reconfigured so that the signal processing device conducts processes relating to signals transmitted to and from a connected external device, the signal processing device comprising:
memory operable to store first configuration information and second configuration information to be used for reconfiguring the first and second reconfigurable circuits; and
a control unit operable to perform such control that:
at a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the external device and an internal interface connected to an internal device, with the first reconfigurable circuit inserted into the signal transmission path; and
at a second temporal point that is after completion of the reconfiguration of the second reconfigurable circuit, the signal transmission path is altered to insert the second configurable circuit between the first reconfigurable circuit and the internal interface.

2. The signal processing device according to claim 1, wherein
the first reconfigurable circuit having been reconfigured conducts a process of converting a signal format between an internal format and an external format, the internal and external formats being mutually different and supported by the internal and external devices, respectively,
the second reconfigurable circuit having been reconfigured conducts a process of changing data carried by the signal in the internal format, without changing the format,
the signal processing device further comprises a selector located in the signal transmission path between the first reconfigurable circuit and the internal interface, the selector being operable to switch a connection topology relating to whether or not the second configurable circuit is inserted, and
the control unit is operable to:
sequentially feed the first configuration information to the first reconfigurable circuit and the second configuration information to the second reconfigurable circuit from the memory, thereby to cause the reconfiguration of each reconfigurable circuit; and
control the selector to switch the connection topology so that the second reconfigurable circuit is not inserted at the first temporal point, and that the second reconfigurable circuit is inserted at the second temporal point.

3. The signal processing device according to claim 2, wherein
the external device is an image signal input device, the first reconfigurable circuit having been reconfigured is operable to conduct the format conversion process through which an image signal received in the external format from the input device via the external interface is converted into the internal format, and to output the image signal converted into the internal format, and
the second configurable circuit having been reconfigured is operable to conduct the data change process through which the image signal received in the internal format from the first reconfigurable circuit having been reconfigured is corrected, and to output the corrected image signal to the internal interface.

4. The signal processing device according to claim 3, further including a third reconfigurable circuit and a fourth reconfigurable circuit, a logic configuration of each reconfigurable circuit being alterable, wherein
the signal processing device is additionally connected to a display device,
the memory is further operable to store third configuration information and fourth configuration information to be used for reconfiguring the third and fourth reconfigurable circuits,
the signal processing device further comprises a second control unit operable to perform such control that:
at a temporal point that is after completion of reconfiguration of the third reconfigurable circuit based on the third configuration information and before completion of reconfiguration of the fourth reconfigurable circuit based on the fourth configuration information, a second signal transmission path is formed between a second external interface connected to the display device and a second internal interface connected to a second internal device, with the third reconfigurable circuit inserted into the second signal transmission path;
at a temporal point after completion of the reconfiguration of the fourth reconfigurable circuit based on the fourth configuration information, the second signal transmission path is altered to inset the fourth reconfigurable circuit between the third reconfigurable circuit and the second internal interface, and
at a temporal point that is after completion of the reconfiguration of the first reconfigurable circuit, the second control unit is operable to sequentially feed the third configuration information to the third reconfigurable circuit and the fourth configuration information to the fourth reconfigurable circuit from the memory, thereby to cause the reconfiguration of each of the third and fourth reconfigurable circuits.

5. The signal processing device according to claim 2, wherein
the external device is a display device,
the second reconfigurable circuit having been reconfigured is operable to conduct the data change process through which an image signal received in the internal format from the internal device via the internal interface is corrected, and to output the corrected image signal in the internal format to the first reconfigurable circuit having been reconfigured, and
the first reconfigurable circuit having been reconfigured is operable to conduct the format conversion process through which the image signal received in the internal format from the second reconfigurable circuit having been reconfigured is converted into the external format, and to output the image signal converted into the external format to the display device via the external interface.

6. The signal processing device according to claim 1, further including a third reconfigurable circuit, a logic configuration of the third reconfigurable circuit being alterable, wherein
the second configuration information is stored in the memory in a compressed state,
the memory is further operable to store, in a non-compressed state, third configuration information to be used for reconfiguring the third reconfigurable circuit,
at a temporal point after completion of the reconfiguration of the first reconfigurable circuit based on the first configuration information and before the second configuration information is started to be fed to the second reconfigurable circuit, the control unit is further operable to feed the third configuration information to the third reconfigurable circuit from the memory, thereby to cause the reconfiguration of the third reconfigurable circuit, and
the third reconfigurable circuit having been reconfigured based on the third configuration information is operable to decompress the second configuration information fed from the memory, and
the control unit is further operable to feed to the second reconfigurable circuit the second configuration information decompressed by the third reconfigurable circuit having been reconfigured, thereby to cause the reconfiguration of the second reconfigurable circuit.

7. The signal processing device according to claim 6, wherein
the memory is further operable to store, in a non-compressed state, fourth configuration information to be used for reconfiguring the third reconfigurable circuit, and
at a temporal point after completion of the reconfiguration of the second reconfigurable circuit, the control unit is operable to:
feed the fourth configuration information to the third reconfigurable circuit from the memory, thereby to cause the reconfiguration of the third reconfigurable circuit; and
to alter the signal transmission path to insert the third reconfigurable circuit between the second reconfigurable circuit and the internal interface.

8. The signal processing device according to claim 1, further including a third reconfigurable circuit and a fourth reconfigurable circuit, a logic configuration of each reconfigurable circuit being alterable, wherein
the second configuration information is stored in the memory in a compressed state,
the memory is further operable to store, in a non-compressed state, third configuration information, fourth configuration information, and fifth configuration information to be used for reconfiguring the third and fourth reconfigurable circuits,
at a temporal point after completion of the reconfiguration of the first reconfigurable circuit based on the first configuration information and before the second configuration information is started to be fed to the second reconfigurable circuit, the control unit is further operable to feed the fifth configuration information to the fourth reconfigurable circuit from the memory, thereby to cause reconfiguration of the fourth reconfigurable circuit,
the fourth reconfigurable circuit having been reconfigured based on the fifth configuration information is operable to feed the third configuration information to the third reconfigurable circuit from the memory, thereby to cause reconfiguration of the third reconfigurable circuit,
the third reconfigurable circuit having been reconfigured based on the third configuration information is operable to decompress the second configuration information fed from the memory,
the fourth reconfigurable circuit having been reconfigured based on the fifth configuration information is operable to feed, to the second reconfigurable circuit, the second configuration information decompressed by the third reconfigurable circuit having been reconfigured, thereby to cause the reconfiguration of the second reconfigurable circuit, and
at a temporal point after completion of the reconfiguration of the second reconfigurable circuit, the fourth reconfigurable circuit having been reconfigured is further operable to:
feed the fourth configuration information to the third reconfigurable circuit from the memory, thereby to cause reconfiguration of the third reconfigurable circuit; and
alter the signal transmission path to insert the third reconfigurable circuit between the second reconfigurable circuit and the internal interface.

9. The signal processing device according to claim 8, wherein
the memory is further operable to store, in a non-compressed state, sixth configuration information to be used for reconfiguring the fourth reconfigurable circuit, and
at a temporal point after completion of the reconfiguration of the third reconfigurable circuit based on the fourth configuration information, the control unit is further operable to feed the sixth configuration information to the forth reconfigurable circuit from the memory, thereby to cause reconfiguration of the fourth reconfigurable circuit.

10. A signal processing method to be used by a signal processing device including a first reconfigurable circuit and a second reconfigurable circuit, a logic configuration of each reconfigurable circuit being alterable, and the reconfigurable circuits being sequentially reconfigured so that the signal processing device conducts processes relating to signals transmitted to and from a connected external device, the signal processing device further including memory for storing first configuration information and second configuration information to be used for reconfiguring the first and second reconfigurable circuits,
the signal processing method comprising a control step in which:
at a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the external device and an internal interface connected to an internal device, with the first reconfigurable circuit inserted into the signal transmission path; and
at a second temporal point that is after completion of the reconfiguration of the second reconfigurable circuit, the signal transmission path is altered to insert the second configurable circuit between the first reconfigurable circuit and the internal interface.

11. An integrated circuit for signal processing, the integrated circuit including a first reconfigurable circuit and a second reconfigurable circuit, a logic configuration of each reconfigurable circuit being alterable, and the reconfigurable circuits being sequentially reconfigured so that the integrated circuit conducts processes relating to signals transmitted to and from a connected external device, the integrated circuit comprising:
memory operable to store first configuration information and second configuration information to be used for reconfiguring the first and second reconfigurable circuits; and
a control unit operable to perform such control that:
at a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the external device and an internal interface connected to an internal device, with the first reconfigurable circuit inserted into the signal transmission path; and
at a second temporal point that is after completion of the reconfiguration of the second reconfigurable circuit, the signal transmission path is altered to insert the second configurable circuit between the first reconfigurable circuit and the internal interface.

12. The integrated circuit according to claim 11, further including a third reconfigurable circuit and a fourth reconfigurable circuit, a logic configuration of each reconfigurable circuit being alterable, wherein
the integrated circuit is additionally connected to a second external device,
the memory is further operable to store third configuration information and fourth configuration information to be used for reconfiguring the third and fourth reconfigurable circuits,
the integrated circuit further comprises a second control unit operable to perform such control that:
at a temporal point that is after completion of reconfiguration of the third reconfigurable circuit based on the third configuration information and before completion of reconfiguration of the fourth reconfigurable circuit based on the fourth configuration information, a second signal transmission path is formed between a second external interface connected to the second external device and a second internal interface connected to a second internal device, with the third reconfigurable circuit inserted into the second signal transmission path; and
at a temporal point after completion of the reconfiguration of the fourth reconfigurable circuit based on the fourth configuration information, the second signal transmission path is altered to inset the fourth reconfigurable circuit between the third reconfigurable circuit and the second internal interface, and
after completion of the reconfiguration of the first reconfigurable circuit, the second control unit is operable to sequentially feed the third configuration information to the third reconfigurable circuit and the fourth configuration information to the fourth reconfigurable circuit from the memory, thereby to cause the reconfiguration of each of the third and fourth reconfigurable circuits.

13. A television receiver including a display, a first reconfigurable circuit and a second reconfigurable circuit, a logic configuration of each reconfigurable circuit being alterable, and the reconfigurable circuits being sequentially reconfigured so that the television receiver conducts processes relating to broadcast signals to be output to the display, the television receiver comprising:
memory operable to store first configuration information and second configuration information to be used for reconfiguring the first and second reconfigurable circuits; and
a control unit operable to perform such control that:
at a first temporal point that is after completion of reconfiguration of the first reconfigurable circuit based on the first configuration information and before completion of reconfiguration of the second reconfigurable circuit based on the second reconfigurable circuit, a signal transmission path is formed between an external interface connected to the display and an internal interface connected to an internal device for conducting a process related to received broadcast signals, with the first reconfigurable circuit inserted into the signal transmission path; and
at a second temporal point that is after completion of the reconfiguration of the second reconfigurable circuit, the signal transmission path is altered to insert the second configurable circuit between the first reconfigurable circuit and the internal interface.
